(19) United States
(12) Patent Application Publication
(10) Pub. No.: US 2010/0275845 A1
(43) Pub. Date: Nov. 4, 2010

(54) ULTRAVIOLET-RESISTANT MATERIALS AND DEVICES AND SYSTEMS INCLUDING SAME

(75) Inventor: Yasuo Kogure, Saitama (JP)

Correspondence Address: KLARQUIST SPARKMAN, LLP, 121 SW SALMON STREET, SUITE 1600, PORTLAND, OR, 97204, US

(73) Assignee: HOYA CANDEO OPTRONICS CORPORATION, Saitama (JP)

(21) Appl. No.: 12/048,117

(22) Filed: Mar. 13, 2008

(30) Foreign Application Priority Data
Mar. 30, 2007 (JP) JP2007-092510

(51) Int. Cl. B65D 25/54; B32B 19/02; B32B 5/16; C23C 16/48; C09D 1/00; C08K 3/34; G02B 13/14; G21K 5/02

(52) U.S. Cl. 118/722; 428/454; 118/733; 106/286.5; 524/445; 359/361; 250/492.1; 250/504 R; 220/663

(57) ABSTRACT

UV-resistant materials are disclosed that include at least one self-supporting film of UV-resistant clay particles and that are substantially non-reactive to incident UV radiation. An exemplary material is substantially non-transmissive to at least one UV wavelength of less than 300 nm, can include a polymeric material for enhanced flexibility, and can include an additive that is non-transmissive to at least one UV wavelength of greater than 300 nm. The material can be multiple layers of respective clay films. The materials can be used to form UV-resistant devices such as seals, mounting cushions, and light-shields for use in any of various UV-illumination sources and process systems. An example UV-illumination source is an excimer laser. An example system is a light-CVD system.

### CROSS-REFERENCE TO RELATED PATENT APPLICATION

This application claims priority to, and the benefit of, Japan Patent Application No. JP 2007-092510, filed on 30 Mar., 2007, the disclosure of which is incorporated herein by reference in its entirety.

### FIELD

This disclosure pertains to, inter alia, materials that are resistant to ultraviolet (UV) radiation and that are usable in UV-irradiation environments. The materials have particular utility as seals, mounting cushions, light-shields, and the like, as used in UV optical systems and optical elements thereof, UV-illumination devices, and process systems utilizing UV radiation.

### BACKGROUND

Certain types of UV-illumination devices apply excitation energy to a rare gas in an air-tight chamber to produce UV radiation. An example is an excimer laser. Also, certain UV-process systems direct UV radiation and a process gas into a chamber in which a workpiece or other process material is placed, and utilize the product of a reaction of the UV radiation and the rare gas to process (e.g., add material to) the surface of the workpiece. The chambers used in these devices and systems usually include a UV-transmissive window made, for example, of a multi-component glass, quartz, or a crystalline material that can transmit UV radiation into or out of the chamber as required.

Whenever a light-transmissive window is mounted to the wall of an air-tight chamber, vessel or the like, a seal must be provided around the window to ensure air-tightness of the bond between the window and the chamber wall. Light-transmissive windows, especially UV-transmissive windows, are usually less durable than the chamber walls and require periodic replacement. Since wall-to-window seals made of metal are difficult to fabricate and use, a more flexible seal, such as an O-ring, is usually used.

O-rings for sealing around chamber windows are usually made of any of various organic elastomers, silane elastomers (“silicone rubber”), or fluorinated elastomers. Under prolonged exposure to UV radiation, most of these materials (especially the organic materials) experience significant degradation and/or decomposition from destructive effects of incident UV radiation on the material. These reactions frequently are accompanied by release of vapors, gases, and/or other contamination into the chamber, which degrades the purity of the process gas in the chamber, compromises the seal, and/or reduces the vacuum level inside the chamber. A conventional way to reduce this problem is to place the O-ring at a suitable distance from areas of the window receiving UV radiation so that the O-ring is not directly exposed to the radiation.

Unfortunately, some of the UV radiation reaching the window propagates to the O-ring by multiple internal reflections of the radiation inside the window from the front and rear surfaces of the window. Even UV-irradiation of the seal in this manner degrades the purity of the process gas inside the chamber, degrades or destroys the seal, and/or compromises the vacuum level inside the chamber.

A conventional approach for addressing this problem of UV radiation reaching the seal by internal reflection involves placing a metallic light-shield between the window and the O-ring. The light-shield essentially blocks internally reflected UV light from reaching the seal. This approach as employed with a window used for transmitting UV light produced by an excimer laser is discussed in Japan Laid-Open Patent Publication No. JP 06-29160. Certain aspects of this approach are depicted in FIG. 9, which shows the laser-beam extraction portion of a KrF excimer laser oscillator 101. The laser oscillator 101 includes a window 102 mounted to walls 104 of a laser chamber. The window 102 is transmissive to the UV laser light produced inside the chamber and thus allows a beam of the laser light to exit the chamber for use downstream. The window 102 is mounted to the walls 104 using an elastomeric (e.g., rubber) O-ring 106. On a surface of the window 102 facing the O-ring 106, an aluminum film 110 has been formed for blocking internally reflected UV light 120 from reaching the O-ring 106. The only practical technique for forming the aluminum film 110 on the surface of the window 102 is vacuum-evaporation, which is difficult to perform in selected areas of the window, especially on a large window.

The aluminum film 110 is vulnerable to oxidation. To inhibit oxidation, an antioxidant film 111 is formed on the surface of the aluminum film so as to be situated between the aluminum film 110 and the O-ring 106. The antioxidant film 111 is made of magnesium fluoride, also formed by vacuum-evaporation. Magnesium fluoride is a known inhibitor of aluminum oxidation. Again, vacuum evaporation is difficult to perform in selected areas of the window, especially on a large window.

Hence, forming a metallic UV-blocking film and an antioxidant film on selected regions of a UV-transmissive window for light-shielding purposes requires two separate vacuum-evaporation steps, which are expensive and difficult. Also, it is difficult to form the aluminum film and magnesium fluoride film evenly around the periphery of the window. These difficulties result in a conventional window being very costly to produce.

### SUMMARY

In view of the foregoing, various aspects of the invention as disclosed herein provide ultraviolet-radiation-resistant (“UV-resistant”) materials and devices that can be used in UV-radiation environments as, for example, seals, mounting cushions, light-shields, and the like. The seals, mounting cushions, light-shields, and the like, formed of such material can be made by methods that do not involve vacuum evaporation or other process performed on a window or other substrate. For example, these devices formed of the UV-resistant material can be fabricated separately and then applied to or placed relative to a window or other component. The seals, mounting cushions, light-shields, and the like can be used in, for example, UV-optical systems of UV-illumination devices and as used in processing systems that utilize UV light.

The UV-resistant materials and devices made therefrom comprise one or more thin films made of clay. The “clay thin film” has self-supporting mechanical strength and flexibility, and thus can be worked to form devices such as seals, mounting cushions, light-shields, or the like. Also, and quite advantageously, the clay thin films and devices comprising them are not adversely affected by incident UV radiation.

Hence, according to a first aspect, clay thin films and membranes are provided that are resistant to UV radiation, are flexible, and are mechanically self-supporting. The clay thin films and materials comprising them are suitable for forming into and use as UV-blocking structures. Upon being irradiated with UV radiation, the subject membranes and films do not degrade and also retain their UV-blocking ability for long periods of time.

According to a second aspect, UV-resistant seals are provided that are made of or comprise one or more clay membranes or thin films. The seals are non-reactive to incident UV radiation and are impervious to liquids and gases, even in UV-radiation environments. Thus, the seals can be used for extended periods of time in UV-radiation environments without exhibiting substantial loss of sealing ability.

According to another aspect, mounting cushions, mounting seats, mounting pads, and force-buffers (collectively called “mounting cushions”) are provided that are made of or comprise one or more clay membranes or films. The mounting cushions are non-reactive to incident UV radiation and are flexible and workable. They can be effectively used in UV-irradiation areas for dispersing clamping forces and other compressive forces being applied to a fragile optical element for mounting or holding purposes.

According to another aspect, UV light-shields are provided that are made of or comprise one or more clay membranes or thin films. The UV light-shields are non-reactive to incident UV radiation and are non-transmissive to incident UV light. They can be used effectively as shields for blocking UV light in the vicinity of areas being irradiated with or receiving UV light. Such a light-shield can be used, for example, to protect and prolong the useful life of a window seal comprising a UV-sensitive organic material. The light-shield is especially advantageous in situations in which the irradiating UV light has a wavelength of less than 300 nm. For example, the light-shield effectively blocks about 100% of incident UV light of wavelength 254 nm (from a mercury lamp) or of wavelength 172 nm (vacuum UV from a xenon excimer laser).

According to a yet another aspect, illumination devices are provided that comprise a UV radiation source and that comprise the UV-resistant, clay-thin-film material strategically situated at an area irradiated with the UV radiation from the source. Since the UV-resistant material is located in a UV-irradiated area, the area can be used for extended periods without down-time that otherwise would be required to rectify the consequences of UV-induced degradation in the area. The UV source can comprise, for example, an excimer laser. In an excimer laser, molecules of a rare gas or rare-gas mixture are excited by an applied electric or magnetic field to produce the laser light. Example rare gases used in the excimer laser include one or more of fluorine, argon, krypton, and xenon. The UV-resistant, clay-thin-film material is placed in selected regions illuminated by UV light from the excimer laser, such as around a window that is transmissive to the laser light. But, the selected regions containing the UV-resistant material do not experience UV-induced degradation because the material is resistant to the UV light produced by the excimer laser. Thus, for example, the UV-resistant, clay-thin-film material can be used as a window seal or other seal in the excimer laser. Since the seal is not compromised by exposure to the excimer-laser light, the purity of the rare gas used in the excimer laser is maintained, allowing the illumination device to operate for long periods without maintenance.

According to yet another aspect, illumination devices are provided that comprise, as a light source, a laser oscillator that operates by stimulated emission of light from an excited gas, liquid, or solid substance. The illumination devices include the UV-resistant, clay-thin-film material at location(s), such as seals, mounting cushions, and light-shields, receiving intense laser light from the source. Since these locations are resistant to degradation that otherwise would be caused by the intense laser light, the light source is not compromised, allowing the illumination devices to be operated for long periods without down-time.

According to yet another aspect, process systems are provided that comprise a hermetically sealed (air-tight) chamber and a UV-transmissive window located at a region on the wall of the chamber. The window comprises the UV-resistant, clay-thin-film material, as summarized above, in at least one region thereof that is irradiated by UV radiation produced in or entering the chamber. Since the process system includes the UV-resistant material at otherwise UV-vulnerable area(s) receiving UV radiation, the system can be operated for extended periods.

The UV-resistant material used in the various aspects summarized above comprises a film or membrane of a clay material (hereinafter termed a “clay thin film”). A clay thin film can be formed in the following manner: Particles of a selected clay material are added to a carrier liquid (e.g., an aqueous liquid) to produce a uniform liquid suspension of the clay particles. The liquid suspension is deposited on a support surface to form a layer of the suspension on the support surface. The carrier liquid is removed at a suitable rate while maintaining the integrity of the layer. Removal of the carrier liquid can be achieved by any of various liquid-solid separation techniques including, but not limited to, centrifugation, filtration, vacuum drying, freeze vacuum drying, or heat-based evaporation. As the carrier liquid is removed, a thin film of oriented clay particles (which do not evaporate) is formed; the thin film also includes other non-volatile materials originally in the liquid suspension. The clay thin film is sheet-like, is flexible, and is sufficiently strong to be self-supporting. Thus, the clay thin film can be removed (e.g., by peeling or lifting) from the support surface without damaging the film. As used herein, a “self-supporting mechanical strength” means that the clay thin film as removed from the support surface is usable as a film that can be worked and shaped without having to remain on the support surface.

The clay thin film desirably comprises, as its main structural component, any of the following clay materials: mica and other mica-group clays; vermiculite and other vermiculite-group clays; and smectic-group clays such as, but not limited to, montmorillonite, iron-montmorillonite, bidellite, saponite, hectorite, stevensite, and nontronite, and mixtures thereof. Clays from the mica group, vermiculite group, and smectic group are phylosilicate clays, characterized as having a crystal structure as multiple layers of thin “boards” and a charge layer between the board layers. The charge layers affect the nature of the clay. E.g., the smectic group has 0.2 to 0.6 of layer charge; the boards separate when the clay is placed in water and return to their original crystalline structure when dried. These various clay materials, how to produce them, and certain properties of them, are discussed in Japan Laid-Open Patent Publication No. 2005-104133, incorporated herein by reference in its entirety. The properties include flexibility, heat-resistance, and resistance to certain gases and liquids.

A “UV-resistant” clay thin film material as disclosed herein desirably is not degraded by the energy of incident UV radiation of one or more wavelengths including a wavelength of less than approximately 380 nm.

A “seal” is a thing used for retaining the hermetic integrity of an air-tight chamber containing a space that is evacuated to a desired vacuum level and/or that contains a particular gas or gas mixture while usually excluding air. Seals are disposed between, for example, members defining the chamber, such as between a wall and a window.

A “mounting cushion” is a force-buffering device used for dispersing or absorbing a clamping force or other mounting force being applied to a member contacted by the mounting cushion. The member can be an optical element, particularly a fragile one. Exemplary optical elements of this nature are made of a material such as, but not limited to, multi-component glass, quartz, or crystal. The optical element can be, for example, a window attached to a portion of an air-tight chamber. The optical element also can be a lens, a mirror, a grating, a filter, or the like.

A “light-shield” is a device situated and configured to block impingement of UV radiation on a respective region of a UV-sensitive material (e.g., an organic material). The UV-sensitive material can be located inside the chamber, such as in the vicinity of a UV-optical element or at a location (e.g., a window) at which UV light enters or exits the chamber. The light-shield extends the useful life of materials that otherwise would be degraded by incident UV radiation.

An “air-tight chamber” is a sealed or sealable chamber in which the atmosphere is evacuated to a desired vacuum level and/or contains a designated gas or gas mixture at a desired pressure (usually subatmospheric), usually while excluding incursion of air into the chamber. The chamber can be made of any of various metals (e.g., stainless steel or aluminum) or any of various rigid inorganic materials such as glass or ceramic. The air-tight chamber can include a gas inlet and optionally a gas outlet that controllably introduce, maintain, and/or circulate the particular atmosphere inside the chamber.

A “UV-transmissive window” is an optical element of which a function is to transmit UV radiation from one side of the window to the other side. The UV-transmissive window desirably has a planar shape but can be lenticular if desired. The window can be made of, for example, multi-component glass or quartz, or of a crystalline material such as magnesium fluoride, calcium fluoride, or sapphire. As noted, the surfaces of the UV-transmissive window can be lenticular, and thus are not limited to planar surfaces. A lenticular surface can be spherical or non-spherical, concave or convex, as required or appropriate. The UV-transmissive window can be wavelength-selective, transmitting UV light only of a particular wavelength, particular wavelengths, or one or more particular ranges of wavelengths. Hence, the window can transmit all or a portion of incident light. To such end, the window can be configured with a partial reflection capability, a polarizing capability, a diffraction capability, a deflection capability, or other suitable optical capability to control transmission and exclusion of light. The window can comprise an anisotropic medium.

A “processing system” comprises an air-tight chamber in which a process is conducted on a material or workpiece. A portion of the chamber includes a UV-transmissive window allowing passage of desired wavelength(s) of incident UV radiation. The material or workpiece is placed in the air-tight chamber and is processed by the UV radiation passing through or otherwise interacting with the UV-transmissive window.

The various aspects summarized above are based in part on a discovery of certain unexpected characteristics of the subject clay thin films, including UV-resistance, flexibility, thermo-stability, and inertness to many gases and liquids. The clay thin films comprise an inorganic clay material that is not degraded by incident UV radiation and that is not transmissive to at least certain wavelengths of incident UV radiation.

### BRIEF DESCRIPTION OF THE DRAWINGS

FIG. 1(a) schematically depicts a device that collects gas produced by or released from a clay thin film when the thin film is being irradiated with ultraviolet (UV) light.

FIG. 1(b) is a graph showing an exemplary measurement result produced by the device shown in FIG. 1(a).

FIG. 2 is an elevational section illustrating a method, involving helium leak-detection, for determining the rate of gas release by a clay thin film.

FIG. 3 is a plot of an example spectral transmission characteristic of a clay thin film.

FIG. 4 is an elevational sectional view of a first exemplary excimer laser, comprising an embodiment of a seal and mounting cushion including a clay thin film.

FIG. 5 is an elevational sectional view of a second exemplary excimer laser, comprising a UV-shielding member including a clay thin film.

FIG. 6(a) is an elevational sectional view of a third exemplary excimer laser, comprising a seal and mounting cushion including a clay thin film.

FIG. 6(b) is a detailed view of a portion of the device of FIG. 6(a).

FIG. 7 is an elevational sectional view showing an embodiment of a UV-transmissive window, used with a laser oscillator, including a UV-resistant seal.

FIG. 8 is an elevational sectional view of an embodiment of a light CVD system, comprising a seal and mounting cushion including a clay thin film.

FIG. 9 is an elevational sectional view showing a light-transmitting window of a conventional laser oscillator.

### DETAILED DESCRIPTION OF REPRESENTATIVE EMBODIMENT(S)

The invention is described in the context of representative embodiments that are not intended to be limiting in any way.

First, a description is provided of an exemplary process for producing a clay thin film and of certain UV-resistance characteristics of the clay thin film.

### Forming a Clay Thin Film

An embodiment of a clay thin film is produced from a liquid suspension of clay material. As noted above, the clay material is selected from the mica group, the vermiculite group, and/or the smectic group of clays. These groups are all phylosilicate clays having thin-board crystalline structures and charge layers between the thin boards. The clay material desirably comprises particles each having a crystalline structure with a thickness approximately 1 nanometer and a diameter of less than a few micrometers.

The selected clay material is added to a carrier liquid (e.g., water or aqueous solution) to form a suspension. The range of concentration of the clay, relative to the carrier liquid, 0.5 w/w percent to 10 w/w percent, preferably 1 to 5 w/w percent. Lower concentrations require longer time periods for drying during formation of the clay thin film; higher concentrations may exhibit difficulty in achieving a uniform dispersion of clay particles in the carrier liquid.

In one example, a suspension of montmorillonite clay particles was prepared by adding particles of the clay to water as an exemplary carrier liquid for the clay particles. More specifically, 8.0 g of natural montmorillonite (“Kunipia P,” manufactured by Kunimine Industries Co., Ltd., Japan) were added to 240 cm³ of distilled water to form a suspension. The suspension was mixed to uniformity using a rotary mixer (e.g., model ARE-250 manufactured by THINKY Corporation, Japan). The resulting uniform suspension was poured as a layer into a shallow, square, stainless steel tray having 20-cm dimensions on each side. While keeping the liquid layer flat in the tray, the carrier liquid was removed by drying the tray and contents for five hours in an oven at 150° C. Upon completion of drying, a thin film of clay particles remained on the upper surface of the tray. This “clay thin film” had a thickness of 80 μm and had 20-cm dimensions on each side. The clay thin film had self-supporting mechanical strength and flexibility, and thus could be easily removed intact from the tray and worked (e.g., cut to shape).

A practical range of thickness of the clay thin film is 3 to 150 micrometers, more preferably 5 to 100 micrometers. Depending upon the particular application, the clay thin film can be made having a single ply or having multiple plies. Multiple plies can be made simply by forming successive layers one atop the other. The natural ability of the clay particles to bond to each other ensures good inter-layer bonding without the need for an adhesive.

There normally is no functionality difference in clay thin films having multiple plies versus a single ply of the same thickness. A multiple-ply clay thin film is particularly suitable for use as a seal, such as between mating flanges, compared to a single ply having the same thickness.

### Analysis of Gas Produced by UV-Irradiated Clay Thin Film

An important property of the clay thin film is low gas production when exposed to incident UV radiation, including in a vacuum environment. A measurement of the amount of gas produced by the clay thin film during UV irradiation is a measure of resistance of the film to UV irradiation. This gas measurement can be obtained by gas chromatography-mass spectroscopy (GC-MS) analysis of collected gas, produced during a particular time interval by a certain amount of the clay thin film being irradiated with a certain intensity and wavelength of UV radiation under a selected vacuum condition.

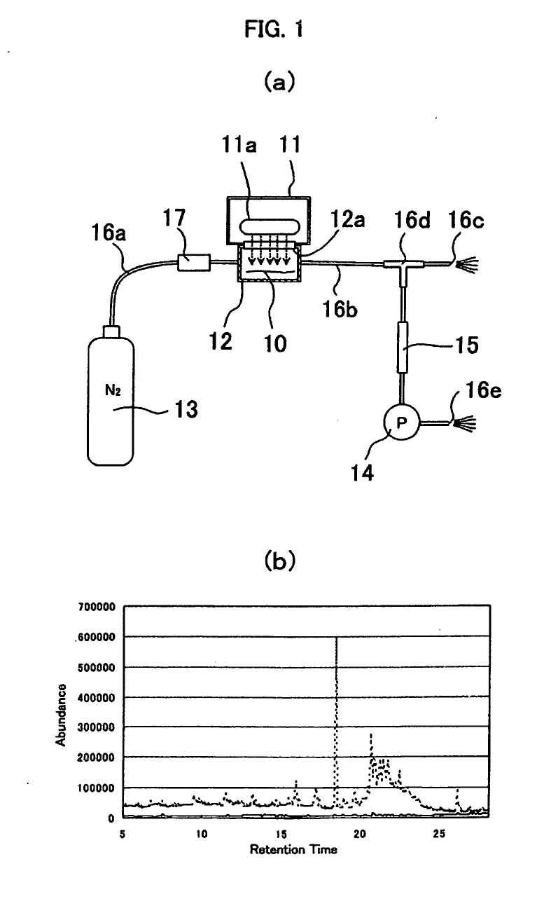

The device used for collecting the gas is shown schematically in FIG. 1(a), in which a stainless-steel, air-tight chamber 12 contains a test piece 10 of the clay thin film. The planar dimensions of the clay thin film are 30-mm square. The air-tight chamber 12 is connected to a UV-radiation device 11, from which UV radiation enters the chamber 12 through a UV-transmissive window 12a made of synthetic quartz. The UV-irradiation device 11 comprises a xenon excimer laser 11a that produces VUV (vacuum UV) radiation having a center wavelength of 172 nm. The VUV radiation from the excimer laser 11a is transmitted through the window 12a to the test piece 10. The intensity of VUV radiation from the excimer laser 11a is about 20 mW/cm² as incident on the surface of the test piece 10 inside the chamber 12.

The air-tight chamber 12 is connected to a supply 13 of 99.999% purity nitrogen (N₂) gas. The N₂ gas passes through an activated-carbon filter 17 which removes, by adsorption, organic material from the N₂ gas. Flow of N₂ gas is 1 L/min through the tube 16a. The tube 16a is made of a fluorinated resin to prevent the tube from contributing any organic material to the N₂ gas. N₂ gas exits the air-tight chamber 12 via a tube 16b (also made of fluorinated resin) and exhaust outlet 16c. The tube 16b includes a branch 16d that leads to a collection tube 15 and pump 14. The collection tube 15 is made of glass and is filled with an absorbing agent (e.g., TENAX-TA®) that collects organic material from gas flowing through the absorbing agent. The pump 14 is connected on the downstream side of the collection tube 15. The pump is controlled to produce a gas flow rate of 60 mL/min passing through the collection tube 15.

Use of the device, shown in FIG. 1(a), to perform a gas measurement is as follows: Before placing the test piece 10 in the chamber 12, and while the collection tube 15 is disconnected from the chamber 12, the xenon excimer laser 11a is run for 30 minutes to pre-expose the chamber 12 to the VUV radiation produced by the laser. This pre-exposure results in decomposition and removal of residual organic material from inside the chamber. Then, the test piece 10 is placed in the chamber 12, and the collection tube 15 is connected. The excimer laser 11a is operated for 50 minutes as the VUV radiation from the laser is transmitted through the window 12a to the test piece 10. Meanwhile, organic material in gas produced by the test piece 10 during this irradiation is collected in the collection tube 15.

At the end of the irradiation period, the collection tube 15 (containing adsorbed organic material released from the test piece 10) is connected to a GC-MS system (not shown). The collection tube 15 is heated to release the organic material for introduction into the GC-MS system. The GC-MS system analyzes the types and relative amounts of organic compounds released by the absorbing agent in the collection tube 15.

As an experimental control, a similar collection and analysis is performed of gas released by a similarly sized sheet of fluorinated rubber irradiated by the same wavelength and intensity of VUV radiation. The fluorinated rubber sheet is representative of an organic material conventionally used for certain types of seals, and thus is an appropriate experimental control.

FIG. 1(b) is a plot of data obtained by the GC-MS system, concerning organic compounds released by the test piece 10 during irradiation by the VUV laser light. In the figure, the solid-line plot is the result of analysis of gas generated by the clay thin film, and the dashed-line plot is the result of analysis of gas generated by the fluorinated rubber sheet. These data show that irradiation of the fluorinated rubber sheet, under vacuum conditions by VUV light having a central wavelength of 172 nm, produces a large amount of organic material. In contrast, a very small amount of organic material is produced by the clay thin film under identical irradiation conditions.

The data also allow a comparison of diffusion rates of organic material from the irradiated surface of the fluorinated rubber and from the irradiated surface of the clay thin film. The determined rates are 4.7 ng/(min·cm²) from the fluorinated rubber and 0.2 ng/(min·cm²) from the clay thin film.

The experiments described above involved irradiation by VUV light having a central wavelength of 172 nm. In otherwise similar experiments performed with UV light having longer wavelengths (namely, 254 nm and 365 nm, respectively), the clay thin film was found to produce substantially no organic material when irradiated.

Thus, the clay thin film is a material that is not degraded by incident UV light. Since the clay thin film also has a self-supporting mechanical strength, it can be made into any of various UV-resistant devices usable in a UV-irradiation environment.

### Evaluation of Air-Tightness of Clay Thin Film

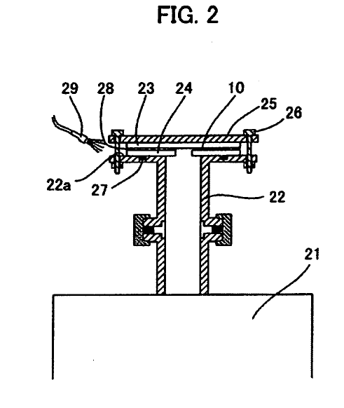

To evaluate the air-tightness (and hence usability as a seal) of the clay thin film produced by the method described above, a helium leak-detection technique was employed. This method is depicted in FIG. 2, in which a helium leak detector 21 is depicted. An exemplary helium leak detector is model M-212LD-D manufactured by Canon Anelva Technix Corporation.

In the technique shown in FIG. 2, a clay thin film 10, having plane dimensions of 20 cm on a side, was trimmed to a test piece having plane dimensions of 30 mm on a side and having a central void 10 mm in diameter. The test piece was mounted between a first glass plate 23 having a thickness of 3 mm and 50-mm sides and a second glass plate 24 having similarly dimensioned sides and thickness but also having a 8-mm diameter central void. The glass plates 23, 24 were mounted on a flange surface 22a of a test port 22. An O-ring 27 produced a seal between the second glass plate 24 and the flange surface 22a. The glass plates 23, 24 were fixed in place using a metal plate 25 and bolts 26.

The interior space defined by the test port 22 was evacuated to a suitable vacuum level. Meanwhile, helium leak detection was performed in the usual manner using the helium leak detector 21. As shown in FIG. 2, helium gas was discharged from a nozzle 29 toward various locations around the test port 22 to determine respective leakage rates of helium gas into the port, especially via the test piece 10 situated in the space 28 between the glass plates 23, 24. Using this technique, the determined rate of helium leak exhibited by the test piece 10 was 1.3×10⁻¹⁰ Pa·m³/sec. This is well within a satisfactory range for use of the test piece 10 as a seal for an air-tight chamber.

In view of the suitability of the UV-resistant material of the clay thin film for use as an air-tight seal, and in view of the flexibility of the clay thin film, the clay thin film is also suitable for use as a mounting cushion or seat for mounting a fragile optical member in an area irradiated by UV radiation. For use as a mounting cushion in this manner, the clay thin film can be used as a single layer or as multiple stacked layers for enhanced force-dissipation. The mounting cushion itself also can serve as an air-tight seal. A seal and/or mounting cushion, made of the UV-resistant material, used as part of an air-tight chamber in this manner is not decomposed by incident UV radiation and does not produce significant amounts of gas in the vacuum-UV environment of such a chamber.

### Spectral-Transmission Characteristic of the Clay Thin Film

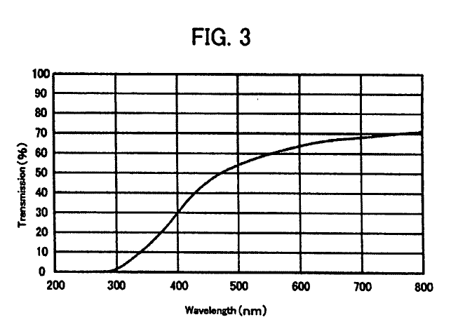

Next, the spectral-transmission characteristic of the clay thin film is determined by evaluating an area thereof that is irradiated by incident UV radiation. This determination permits an evaluation of the UV-blocking effect of the clay thin film. FIG. 3 depicts an exemplary UV-transmission spectrum as a function of wavelength of incident UV radiation. The clay thin film that produced the data of FIG. 3 was produced by the method described above. FIG. 3 shows that the clay thin film has about 30% to 80% transmission to UV wavelength more than 400 nm, and a generally increasing transmission with increasing wavelength in this range. Below 400 nm, the transmission decreases with decreases in wavelength, and the transmission is about 0% to wavelengths less than 300 nm. These transmission-spectrum data were obtained using a U-4000 instrument manufactured by Hitachi, Ltd., Japan.

The obtained data indicate that UV-resistant material comprising a clay thin film can block 100% of incident UV radiation of less than 300-nm wavelength. The clay thin film possesses this property in addition to its flexibility, self-supporting strength, air-tightness, and UV-resistance discussed above. Thus, the clay thin film can be used as a light-shielding member for protecting, e.g., an organic material that otherwise would be difficult to use in association with air-tight chambers in which UV radiation is irradiated.

The UV-blocking and other advantageous properties of the UV-resistant material comprising the clay thin film of this embodiment can be selected and controlled by, for example, selecting a corresponding ratio of clay material to carrier liquid during preparation of the clay dispersion. Also selectable are the planar dimensions of the tray in which the clay dispersion is poured and the depth of the liquid suspension in the tray. By controlling these parameters, the appropriate seals, mounting cushions, and light-blocking members can be fabricated for particular uses.

In this embodiment the UV-resistant material of the clay thin film is natural montmorillonite. Any of various other clays, such as those listed earlier above, can alternatively be used. If desired or required, a small amount of polymeric and/or polymer-forming material (e.g., but not limited to, nylon monomers and/or oligomers) can be added to the clay dispersion during preparation thereof to impart additional flexibility to the clay thin film. As discussed above, certain organic oligomers and polymers are degraded by exposure to UV light. Hence, one might expect that addition of polymeric and/or polymer-forming material to the clay thin film could render the clay thin film more UV-degradable. Applicants have unexpectedly found that, in clay thin films that include polymers, UV-decomposition or UV-degradation of the polymers and/or gas generation from the polymers is prevented or substantially reduced because the clay exhibits a high light-blocking effect for UV radiation. I.e., the clay in the clay thin film blocks UV radiation from reaching most of the polymer molecules. Even better results are obtained by forming the polymer-containing clay thin film with more of its polymer located on the surface opposite the UV-irradiated surface of the clay thin film.

In addition to or instead of adding a polymeric and/or polymer-forming additive, other flexibility-enhancing additives include, but are not limited to, aluminum borate and any of various inorganic fibers (e.g., “whiskers”) such as silicon carbide. A clay thin film containing, as a flexibility enhancer, inorganic fiber tends to exhibit more UV-resistance than a clay thin film containing polymers. This is because inorganic fibers and the like inherently have more UV-resistance and less gas generation when exposed to incident UV radiation.

In addition to the clay material as the UV-resistant material in the clay thin films, a clay thin film can include a colorant additive. Particularly advantageous colorants used in various embodiments are metal ions, such as, but not limited to, iron, copper, cobalt, or nickel. These colorant metal ions are especially useful for blocking UV radiation having a wavelength of greater than 300 nm.

### Second Embodiment

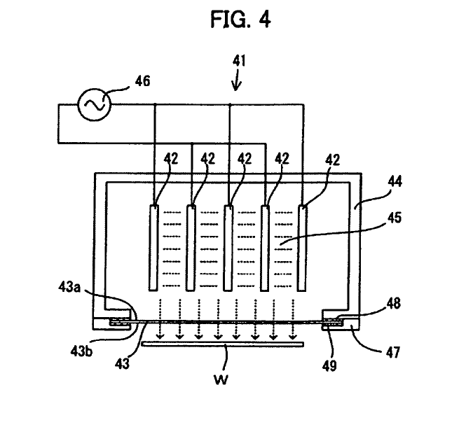

This embodiment, directed to an illumination device comprising a UV-resistant clay thin film, is depicted in FIG. 4. The illumination device, shown in elevational section, comprises an excimer laser 41. The excimer laser 41 comprises a light-transmissive window 43 and an air-tight chamber 44 in which several discharge electrodes 42 face each other. The discharge electrodes 42 are covered by a surface layer of a dielectric material comprising, for example, synthetic quartz. Between the facing electrodes 42 are respective discharge spaces 45. By applying an electric potential to the electrodes 42 from a high-frequency power source 46, electrical discharges are produced between the electrodes. Also, between the electrodes 42 is a gas that forms excited dimers n the presence of the electrical discharge. An example gas is high-purity xenon gas at a pressure of about 1 atmosphere. The energy from the electrical discharges also pumps the excited dimers to produce VUV laser light. The VUV laser light produced when the gas is xenon has a central wavelength of 172 nm. This laser light is transmitted through the light-transmissive window 43.

The shape of the light-transmissive window 43 in this embodiment is round, with a diameter of 150 mm and a thickness of 10 mm. The material of the window 43 is synthetic quartz. The air-tight chamber 44 is cylindrical with a diameter of 200 mm and a height of 150 mm. The walls are made of 8-mm thick stainless steel.

The region of the chamber 44 at which the light-transmissive window 43 is attached includes a seal 48 made of the UV-resistant material comprising a clay thin film. The seal 48 assures attainment and maintenance of the air-tight quality of the chamber 44.

In FIG. 4, the VUV laser light from the discharge space 45 passes through the light-transmissive window 43 and irradiates a material W outside the window 43. The laser light also irradiates an inside surface 43a and an outside surface 43b of the window 43, from which surfaces the light is internally reflected multiple times. Consequently, some of the VUV light reaches the seal 48. However, because the seal 48 comprises the UV-resistant clay thin film of this embodiment, the seal is not decomposed or degraded by the incident VUV. Thus, the air-tightness of the chamber 44 is maintained. Maintenance of air-tightness maintains the high purity as well as the proper concentration of xenon gas in the chamber 44, allowing the excimer laser 41 to continue producing laser light for long periods.

In this embodiment, between the light-transmissive window 43 and a clamping frame 47 is a mounting cushion or seat 49 comprising five layers of UV-resistant clay thin film. Each layer is produced as described above, formed one layer atop the other. The multi-layer structure of the mounting cushion 49 increases its thickness and allows it more effectively to disperse clamping pressure applied by the frame 47 to the window 43. The mounting cushion 49 receives internally reflected excimer-laser light, especially such light that has been internally reflected inside the window 43 as described above. However, since the mounting cushion 49 comprises the UV-resistant clay thin film, the mounting cushion is not degraded or decomposed by the excimer-laser light, which allows the mounting cushion to disperse clamping force applied by the frame 47 for a long period of time.

This embodiment also maintains the air-tightness of the light-transmissive window 43 relative to the chamber 44 without having to form layers of aluminum and magnesium fluoride around the periphery of the window. Depending upon the profile irregularity of either or both surfaces of the chamber 44 and clamping frame 47, the number of layers of the clay thin film utilized in the seal 48 and/or mounting cushion 49 can be changed as appropriate.

### Third Embodiment

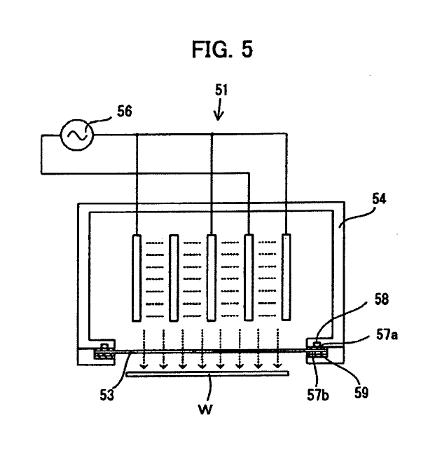

This embodiment is similar in certain ways to the illumination device of the second embodiment. The main difference between the two embodiments is in the manner of mounting the light-transmissive window. The third embodiment is depicted in FIG. 5 as a schematic elevational sectional view, Shown are an excimer laser 51 comprising electrodes situated inside an air-tight chamber 54. A light-transmissive window 53 is mounted to the chamber 54. In the second embodiment, the seal 48 and mounting cushion 49 for mounting the window 43 are both UV-resistant materials comprising the clay thin film. In this third embodiment, as shown in FIG. 5, the seal 58 and mounting cushion 59 are made of other materials, and shields 57a, 57b are included that are UV-resistant materials comprising the clay thin film.

More specifically, in FIG. 5, the seal 58 is a fluorinated resin O-ring, and the mounting cushion 59 is made of Gore-Tex®. The shields 57a, 57b are shape-cut UV-resistant material comprising the clay thin film, formed as described earlier above. The shields 57a, 57b protect the O-ring 58 and the mounting cushion 59 from incident UV radiation produced by the excimer laser 51.

By using existing seals and/or mounting cushions made of organic materials and protecting them by easy-to-install UV-resistant shields according to this embodiment, excimer light does not reach the organic materials. Thus, the rate of decomposition of the organic material is substantially reduced while utilizing the existing air-tightness and/or flexibility of the organic material.

In this embodiment, the seal 58, mounting cushion 59, and shields 57a, 57b are formed separately and simply placed together. It is alternatively possible to add UV-blocking capability to the seal 58 and/or mounting cushion 59 by coating, laminating, or forming, on at least the surfaces reached by UV, at least one inorganic material. Even in such an alternative embodiment, the air-tightness and flexibility of the inorganic material are preserved.

### Fourth Embodiment

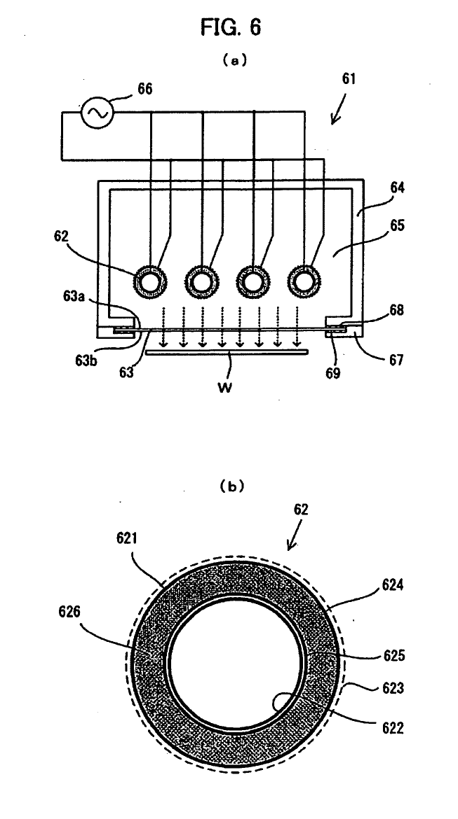

This embodiment is directed to another configuration of an illumination device comprising a laser housing containing multiple individual excimer-laser devices. FIG. 6(a) is a schematic elevational sectional view of the illumination device 61. The illumination device 61 comprises a laser housing 64 and a UV-transmissive window 63. The laser housing 64 comprises multiple excimer-laser devices 62 arranged in parallel with the window 63. As shown in FIG. 6(b), an excimer-laser device 62 comprises a cylindrical hollow discharge container 621. The discharge container 621 includes electrodes 622, 623 formed on the outside and inside surfaces, respectively, of the container 621. The discharge container 621 also has an inner tube 624 and an outer tube 625 each made of synthetic quartz. The tubes 624, 625 have different respective diameters, and are coaxial with the electrodes 622, 623. Both ends of the container 621 are closed. Xenon gas, used as a laser-discharge gas, fills a discharge space 626 situated between the outer tube 624 and the inner tube 625. The xenon gas is energized and pumped as a laser medium by applying a high-frequency, high electrical potential across the discharge electrodes 622, 623, resulting in production of excimer-laser light of 172 nm wavelength peak emission.

In FIG. 6(a), the housing 64 containing the excimer lasers 62 is filled with an inert gas (e.g., N₂ gas) to prevent attenuation of the excimer-laser light that otherwise would occur in the presence of oxygen. Not shown are a gas-inlet port and a gas-exhaust port for introducing and circulating the inert gas.

Located at the juncture of the light-transmissive window 63 and the housing 64 is a seal 68 made of UV-resistant material comprising the clay thin film. The seal 68 has a specified configuration for maintaining air-tightness of the juncture. Excimer-laser light from the individual lasers 62 passes through the window 63 to irradiate a material W outside the window. In the window 63, the laser light is internally reflected multiple times from the inside surface 63a and outside surface 63b of the window 63. Some of this internally reflected light reaches and irradiates the seal 68. But, since the seal 68 is made of the U V-resistant material comprising the clay thin film, the seal does not degrade. Thus, the air-tightness of the housing 64 is maintained, which prevents oxygen in the outside air from penetrating into the housing. This allows the UV radiation of 172-nm wavelength produced by the excimer lasers 62 to reach the window 63 without being attenuated.

Between the light-transmissive window 63 and a clamping frame 67 is a mounting cushion 69 for relieving clamping stress applied to the window 63 by the frame 67. The mounting cushion 69 in this embodiment comprises five layers of the UV-resistant material comprising the clay thin film. The mounting cushion 69 is irradiated by the excimer-laser light in the same manner as the seal 68 is irradiated (by internal reflection). However, by fabricating the mounting cushion 69 of the UV-resistant material comprising the clay thin film (as used for fabricating the seal 68), the mounting cushion is not decomposed by the excimer-laser light and can continue performing its function of distributing the stress from the clamping frame 67.

In this embodiment of an illumination device 61, by not requiring a vacuum-evaporated film of aluminum or magnesium fluoride around the window 63, it is easy to assure the air-tightness of the window 63 relative to the housing 64.

### Fifth Embodiment

This embodiment is directed to an illumination device in which a laser chamber of a laser oscillator includes a UV-resistant material comprising the clay thin film.

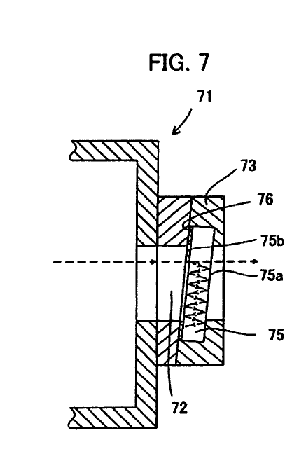

FIG. 7 is a sectional view of the light-emitting portion 72 of the laser chamber 71. The laser chamber 71 utilizes a laser-medium gas, such as a mixture of krypton gas and fluorine gas, tightly sealed within the inner space defined by the laser chamber 71. Also located inside the laser chamber 71 is an excitation electrode (not shown). The electrode excites the laser-medium gas to produce, for example, KrF excited dimers that emit laser light having a center wavelength of 248 nm.

A light-transmissive window 75 is mounted on the light-emitting portion 72; the window 75 transmits the KrF laser light. The window 75 is attached by a mounting member 73. Between the window 75 and the mounting member 73 is a seal 76 formed from the UV-resistant material comprising the clay thin film.

The KrF laser light of 248 nm passes through the window 75 from inside the chamber 71 to outside. Inside the window 75, some of the laser light reflects internally multiple times between the outer surface 75a and the inner surface 75b of the window, and reaches the periphery of the window 75. However, since the seal 76 is made of the UV-resistant material comprising the clay thin film, the seal is not decomposed by the laser light. Thus, the seal 76 can continue its role of preventing gas leaks from the chamber 71 or into the chamber contaminating the laser-medium gas.

In this and other embodiments, the illumination devices comprise excimer lasers or excimer laser oscillators for producing illumination light. This is not intended to be limiting in any way. Various alternative embodiments produce illumination light of wavelengths other than UV.

### Sixth Embodiment

The second through fifth embodiments incorporating the UV-resistant material comprising the clay thin film are example embodiments of illumination devices that produce excimer-laser light. However, devices (e.g., seals, mounting cushions, and shields) made of the UV-resistant material comprising the clay thin film also can be utilized on or with other types of illumination devices. Further alternatively, devices made of the UV-resistant material comprising the clay thin film can be utilized in process systems in which UV light or other intense light is irradiated onto an object situated inside an air-tight chamber. An example system is a light CVD system.

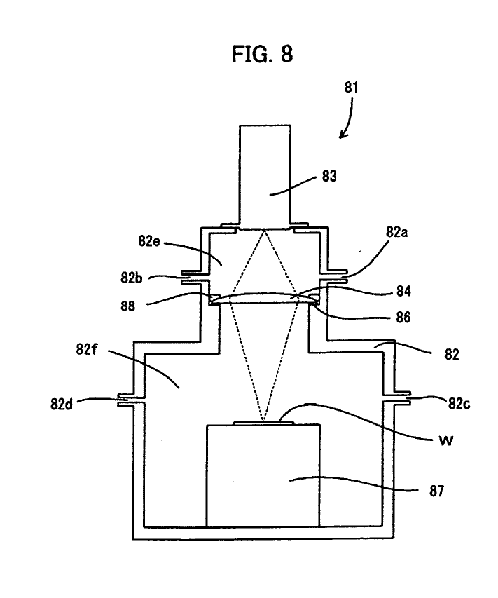

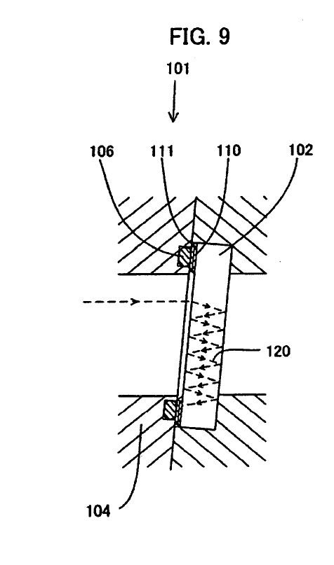

FIG. 8 is a schematic elevational section of an embodiment of a light CVD system 81. The light CVD system 81 comprises an air-tight chamber 82 defining a processing space 82a. A deuterium lamp 83 is situated above the chamber 82 and produces UV light of wavelength 150-300 nm. The UV light is irradiated onto a silicon wafer W placed on a heater 87 inside the chamber 82 (more specifically, the wafer is situated in a processing space 82f). Meanwhile, a reactant gas is circulated through the processing space 82f via ports 82c, 82d. Under these conditions the UV-irradiated reactive gas photoreacts to form a SiO₂ insulating film on the wafer W.

UV light from the deuterium lamp 83 is collected using a condensing lens 84 made of calcium fluoride. The lens 84 converges the UV light onto the surface of the wafer W. In this manner, the lens 84 serves as a light-transmissive window that separates the deuterium lamp 83 from the processing space 82f. More specifically, the lens 84 separates an intermediate space 82e, downstream of the deuterium lamp 83, from the processing space 82f. Any molecules of reactant gas contaminating the intermediate space 82e are removed by passing N₂ gas through the space 82e from an inlet 82a to an outlet 82b.

The condensing lens 84 is mounted to the upper walls of the chamber 82, between the intermediate space 82e and processing space 82f, using a mounting member 88 and a seal 86. The seal 86 has a ring shape and is made of the UV-resistant material comprising the clay thin film. Thus, the condensing lens 84 is located so as to separate the intermediate space 82e from the processing space 82f, and to ensure the air-tightness of the intermediate space 82e relative to the processing space 82f.

The UV light irradiated from the deuterium lamp 83 and passing through the condensing lens 84 is converged by the lens on the surface of the silicon wafer W in the processing space 82f. Meanwhile, a portion of the UV light irradiates the seal 86 as a result of internal reflection inside the condensing lens 84. Since the seal 86 is made of the UV-resistant material comprising the clay thin film, it is not decomposed by the UV light, which allows good and prolonged maintenance of the atmosphere in the processing space 82f.

In this embodiment, the optical CVD system 81 utilizes UV light produced by a deuterium lamp to perform the process on the wafer W. This is not intended to be limiting. A process system including a device made of the UV-resistant material comprising the clay thin film can be any of various other process systems. For example, the processing system can utilize light from a source other than an ultraviolet radiation source, such as an optical cleansing or optical modifying system, or can be a processing system other than an optical CVD system.

Therefore, UV-resistant devices are provided that can be used as seals, mounting cushions, seats, shields, and the like used in conditions of UV irradiation without concern with degradation, deterioration, or the like. Also provided are illumination devices and processing systems comprising at least one such UV-resistant device.

Whereas the invention has been described above in the context of representative embodiments, it will be understood that the invention is not limited to those embodiments. On the contrary, the invention is intended to encompass all alternatives, modifications, and equivalents as may be included within the spirit and scope of the invention, as defined by the appended claims.

What is claimed is:

1. An ultraviolet (UV) radiation-resistant material, comprising at least one self-supporting film of UV-resistant clay particles, the material being substantially non-reactive to UV radiation incident thereon.

2. The material of claim 1, wherein the film is substantially non-transmissive to at least one UV wavelength of less than 300 nm.

3. The material of claim 1, wherein the film further comprises a polymer material.

4. The material of claim 1, wherein the film further comprises fibers.

5. The material of claim 1, further comprising multiple layers of respective clay films.

6. The material of claim 1, wherein the clay particles are substantially uniformly distributed in the film.

7. The material of claim 1, wherein clay particles are of at least one clay material selected from the group consisting of mica-group clay materials, vermiculite-group clay materials, montmorillonite, iron-montmorillonite, bidellite, saponite, hectorite, stevensite, and nontronite, and mixtures thereof.

8. The material of claim 1, wherein the clay particles are oriented.

9. The material of claim 1, further comprising an additive that is non-transmissive to at least one UV wavelength of greater than 300 nm.

10. The material of claim 9, wherein the additive comprises ions of a metal selected from the group consisting of iron, copper, cobalt, and nickel.

11. An ultraviolet (UV) radiation-resistant device, formed of a UV-resistant material comprising at least one self-supporting film of UV-resistant clay particles.

12. The device of claim 11, configured as at least one of a seal, a mounting cushion, and a light-shield.

13. The device of claim 11, wherein the at least one film comprises particles of a clay selected from the group consisting of mica-group clays, vermiculite-group clays, montmorillonite, iron-montmorillonite, bidellite, saponite, hectorite, stevensite, and nontronite, and mixtures thereof.

14. The device of claim 11, wherein the clay film is substantially non-transmissive to UV radiation having at least one wavelength of less than 300 nm.

15. The device of claim 11, further comprising multiple layers of respective films of UV-resistant clay particles.

16. The device of claim 11, wherein the clay particles are substantially uniformly distributed in the film.

17. A chamber, comprising:
chamber walls defining a chamber space;
an ultraviolet (UV) transmissive window having a periphery mounted to at least one chamber wall; and
a UV-resistant device situated between the periphery of the window and the at least one chamber wall, the UV-resistant device comprising at least one film of UV-resistant clay particles, the at least one film being self-supporting and substantially non-reactive to UV radiation incident thereon.

18. The chamber of claim 17, in which the chamber space is evacuated to a selected vacuum level.

19. The chamber of claim 17, in which the chamber space contains a desired gas at a selected pressure.

20. The chamber of claim 17, wherein the at least one clay film comprises particles of a clay selected from the group consisting of mica-group clays, vermiculite-group clays, montmorillonite, iron-montmorillonite, bidellite, saponite, hectorite, stevensite, and nontronite, and mixtures thereof.

21. The chamber of claim 17, wherein the UV-resistant device is substantially non-transmissive to at least one wavelength of UV radiation less than 300 nm.

22. The chamber of claim 17, wherein the UV-resistant device is configured as at least one of a seal, a mounting cushion, and a UV-light-shield.

23. The chamber of claim 17, wherein the UV-resistant device further comprises multiple layers of respective films of UV-resistant clay particles.

24. The chamber of claim 17, further comprising a seal situated between the periphery of the window and the at least one chamber wall, wherein the UV-resistant device is configured as a shield substantially blocking UV radiation from reaching the seal.

25. The chamber of claim 24, wherein the UV-resistant device substantially blocks UV radiation, internally reflecting in the window, from reaching the seal.

26. A chamber, comprising:
chamber walls defining a chamber space;
an object situated inside the chamber space and exposed to ultraviolet (UV) light inside the chamber; and
a UV-resistant device situated relative to the object and exposed to the UV light, the UV-resistant device comprising at least one self-supporting film of UV-resistant clay particles.

27. The chamber of claim 26, configured to admit UV light from outside the chamber to inside the chamber.

28. The chamber of claim 26, further comprising a chamber window, wherein the UV-resistant device is configured as a seal situated between the window and at least one wall of the chamber.

29. The chamber of claim 26, wherein the chamber contains a source of the UV light.

30. An ultraviolet (UV) illumination device, comprising:
a chamber defined by chamber walls;
a UV-source situated in the chamber;
a window mounted to at least one chamber wall; and
a UV-resistant device associated with the window and comprising at least one self-supporting film of UV-resistant clay particles.

31. The device of claim 30, wherein the window is situated to transmit UV light from the source from inside the chamber to outside the chamber.

32. The device of claim 30, wherein the UV-resistant device comprises at least one of a seal, a mounting cushion, and a light-shield.

33. The device of claim 30, wherein:
the UV-resistant device is configured as a seal situated between the window and at least one wall of the chamber; and
the seal further comprises multiple films of UV-resistant clay particles, the films collectively providing a mounting cushion between the window and the at least one wall.

34. The device of claim 30, further comprising a seal situated between the window and at least one wall of the chamber, wherein the UV-resistant device is situated relative to the seal to shield UV radiation from being incident on the seal.

35. The device of claim 30, wherein the clay film comprises particles of a clay material selected from the group consisting of mica-group clays, vermiculite-group clays, montmorillonite, iron-montmorillonite, bidellite, saponite, hectorite, stevensite, and nontronite, and mixtures thereof.

36. The device of claim 30, wherein the UV-source comprises a laser.

37. The device of claim 36, wherein the laser is an excimer laser.

38. The device of claim 30, wherein the UV-source comprises a laser oscillator.

39. A process system, comprising:
an air-tight first chamber defined by respective walls;
an ultraviolet (UV) transmissive window coupled to the walls of the first chamber, the window passing UV radiation from a UV-source to inside the first chamber; and
a UV-resistant material situated to receive a portion of the passed UV radiation, the UV-resistant material comprising at least one self-supporting film of UV-resistant clay particles and being substantially non-reactive to the UV radiation incident thereon.

40. The system of claim 39, further comprising:
a UV-source; and
a second air-tight chamber coupled to the first chamber but separated from the first chamber by the window, the second chamber containing the UV source, wherein the UV radiation produced by the UV-source passes from the second chamber through the window into the first chamber to participate in a process being conducted in the first chamber.

41. The system of claim 39, where the UV-resistant device comprises at least one of a seal, a mounting cushion, and a light-shield.

42. The system of claim 40, wherein the UV-resistant device is configured at least as a UV-resistant seal situated between the window and the walls to which the window is coupled to seal, via the window, the first and second chambers from each other.

43. The system of claim 39, configured as a light-CVD system.
